(19) United States
(12) Patent Application Publication
(10) Pub. No.: US 2010/0221426 A1
(43) Pub. Date: Sep. 2, 2010

(54) Web Substrate Deposition System

(75) Inventor: Piero Sferlazzo, Marblehead, MA (US)

Correspondence Address: RAUSCHENBACH PATENT LAW GROUP, LLP, P.O. BOX 387, BEDFORD, MA, 01730, US

(73) Assignee: FLUENS CORPORATION, Billerica, MA (US)

(21) Appl. No.: 12/395,750

(22) Filed: Mar. 2, 2009

(51) Int. Cl. C23C 16/44; C23C 16/46; C23C 16/458

(52) U.S. Cl. 427/255.26; 118/715; 118/725; 118/724

(57) ABSTRACT

A web substrate atomic layer deposition system includes at least one roller that transports a surface of a web substrate through a plurality of processing chambers. The plurality of processing chambers includes a first precursor reaction chamber that exposes the surface of the web substrate to a desired partial pressure of first precursor gas, thereby forming a first layer on the surface of the web substrate. A purging chamber purges the surface of the web substrate with a purge gas. A vacuum chamber removes gas from the surface of the substrate. A second precursor reaction chamber exposes the surface of the web substrate to a desired partial pressure of the second precursor gas, thereby forming a second layer on the surface of the web substrate.

### BACKGROUND OF THE INVENTION

Chemical Vapor Deposition (CVD) is widely used to deposit dielectrics and metallic thin films. There are many techniques for performing CVD. For example, CVD can be performed by introducing two or more precursor molecules in the gas phase (i.e., precursor gas A molecule and precursor gas B molecule) into a process chamber containing a substrate or work piece at pressures varying from less than 10⁻³ Torr to atmosphere.

The reaction of precursor gas molecule A and precursor gas molecule B at a surface of a substrate or work piece is activated or enhanced by adding energy. Energy can be added in many ways. For example, energy can be added by increasing the temperature at the surface and/or by exposing the surface to a plasma discharge or an ultraviolet (UV) radiation source. The product of the reaction is the desired film and some gaseous by-products, which are typically pumped away from the process chamber.

Most CVD reactions occur in the gaseous phase. The CVD reactions are strongly dependent on the spatial distribution of the precursor gas molecules. Non-uniform gas flow adjacent to the substrate can result in poor film uniformity and shadowing effects in three-dimensional features, such as vias, steps and other over-structures. The poor film uniformity and shadowing effects result in poor step coverage. In addition, some of the precursor molecules stick to a surface of the CVD chamber and react with other impinging molecules, thereby changing the spatial distribution of the precursor gases and, therefore, the uniformity of the deposited film.

### BRIEF DESCRIPTION OF THE DRAWINGS

This invention is described with particularity in the detailed description. The above and further advantages of this invention may be better understood by referring to the following description in conjunction with the accompanying drawings, in which like numerals indicate like structural elements and features in various figures. The drawings are not necessarily to scale, emphasis instead being placed upon illustrating the principles of the invention.

FIG. 1 illustrates a schematic view of a unidirectional ALD web coating system having a linear combination of nine process chambers according to the present invention.

FIG. 2A is a cross-sectional view of a single surface web coating system according to the present invention illustrating a web substrate in a manifold comprising a plurality of chambers.

FIG. 2B is a cross-sectional view of a dual-surface web coating system according to the present invention illustrating a web substrate in a manifold comprising a first plurality of chambers on one side of the web substrate and a second plurality of chambers on the other side of the web substrate.

FIG. 3 illustrates a schematic view of a bi-directional ALD web coating system having a linear combination of the thirteen process chambers according to the present invention.

FIG. 4 illustrates a schematic view of a bi-directional dual-surface web coating system according to the present invention.

FIG. 5 illustrates a schematic view of a bi-directional dual-surface web coating system including a plurality of linear combinations of process chambers according to the present invention.

### DETAILED DESCRIPTION

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

It should be understood that the individual steps of the methods of the present teachings may be performed in any order and/or simultaneously as long as the invention remains operable. Furthermore, it should be understood that the apparatus and methods of the present teachings can include any number or all of the described embodiments as long as the invention remains operable.

The present teachings will now be described in more detail with reference to exemplary embodiments thereof as shown in the accompanying drawings. While the present teachings are described in conjunction with various embodiments and examples, it is not intended that the present teachings be limited to such embodiments. On the contrary, the present teachings encompass various alternatives, modifications and equivalents, as will be appreciated by those of skill in the art. Those of ordinary skill in the art having access to the teachings herein will recognize additional implementations, modifications, and embodiments, as well as other fields of use, which are within the scope of the present disclosure as described herein.

Atomic Layer Deposition (ALD) is a variation of CVD that uses a self-limiting reaction. The term “self-limiting reaction” is defined herein to mean a reaction that limits itself in some way. For example, a self-limiting reaction can limit itself by terminating after a reactant is completely consumed by the reaction. One method of ALD sequentially injects a pulse of one type of precursor gas into a reaction chamber. After a predetermined time, another pulse of a different type of precursor gas is injected into the reaction chamber to form a monolayer of the desired material. This method is repeated until a film having the desired thickness is deposited onto the surface of the substrate.

For example, ALD can be performed by sequentially combining precursor gas A and precursor gas B in a process chamber. In a first step, a gas source injects a pulse of precursor gas A molecules into the process chamber. After a short exposure time, a monolayer of precursor gas A molecules deposits on the surface of the substrate. The process chamber is then purged with an inert gas.

During the first step, precursor gas A molecules stick to the surface of the substrate in a relatively uniform and conformal manner. The monolayer of precursor gas A molecules covers the exposed areas including vias, steps and surface structures in a relatively conformal manner with relatively high uniformity and minimal shadowing.

Process parameters, such as chamber pressure, surface temperature, gas injection time, and gas flow rate can be selected so that only one monolayer remains stable on the surface of the substrate at any given time. In addition, the process parameters can be selected for a particular sticking coefficient. Plasma pre-treatment can also be used to control the sticking coefficient.

In a second step, another gas source briefly injects precursor gas B molecules into the process chamber. A reaction between the injected precursor gas B molecules and the precursor gas A molecules that are stuck to the substrate surface occurs and that forms a monolayer of the desired film that is typically about 1-20 Angstroms thick. This reaction is self-limiting because the reaction terminates after all the precursor gas A molecules are consumed in the reaction. The process chamber is then purged with an inert gas.

The monolayer of the desired film covers the exposed areas including vias, steps and surface structures in a relatively conformal manner with relatively high uniformity and minimal shadowing. The precursor gas A and the precursor gas B molecules are then cycled sequentially until a film having the desired total film thickness is deposited on the substrate. Cycling the precursor gas A and the precursor gas B prevents reactions from occurring in the gaseous phase and results in a more controlled reaction.

Atomic Layer Deposition has been shown to be effective in producing relatively uniform, pinhole-free films having thickness that are only a few Angstroms thick. Dielectrics have been deposited using ALD that exhibit relatively high breakdown voltages and relatively high film integrity compared with other methods, such as PVD, thermal evaporation and CVD.

There have been many attempts to improve the uniformity and integrity of ALD films with varying success. For example, researchers have developed new precursor gas chemistries, new techniques for surface pre-treatment, and new methods for injecting precursor gases at precise times in efforts to improve the uniformity and integrity of ALD films. See, for example, U.S. Pat. No. 6,972,055, which is assigned to Fluens Corporation.

Atomic layer deposition methods and apparatus have been generally limited to conventional substrates. Known ALD techniques are not easily transferred to web coating systems because, in known ALD processes, the substrate is position in a fixed location in the process chamber and the precursors gases are injected sequentially into the process chamber. Web coating systems typically move a web substrate from one roll to another roll. One attempt to perform ALD on a web substrate is described in US Patent Application Publication No. 20060153985. This U.S. Patent Publication describes an apparatus that includes rolls that are wound with a spacer so that, during the ALD process, the precursor gases can flow in between the web substrate. However, the apparatus described in this U.S. Patent Publication is not well suited for sequential processing. In addition, in the apparatus described in this U.S. Patent Publication, the precursor gases do not uniformly coat the entire surface of the web substrate because of the relatively large size and convolution of the rollers.

The ALD processing system according to the present invention is specifically designed for depositing materials on web substrates and is useful for fabricating many devices, such as organic light-emitting diodes (OLEDs), which are light emitting diodes that have emissive electroluminescent layers formed of organic compounds. Currently, OLEDs are fabricated by depositing these emissive electroluminescent layers in rows and columns onto a flat carrier by various known printing process. All of these known printing processes have many limitations.

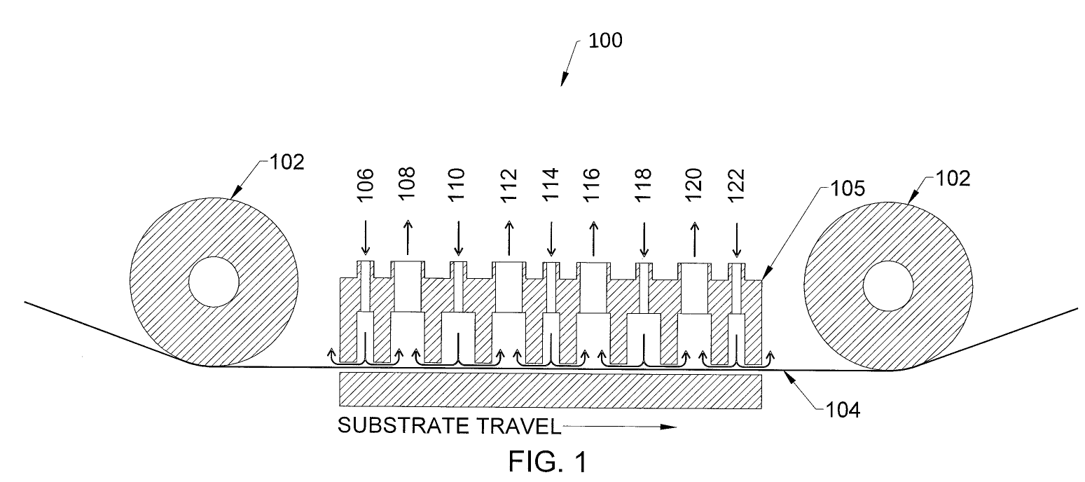

FIG. 1 illustrates a schematic view of a unidirectional ALD web coating system 100 having a linear combination of nine process chambers according to the present invention. The ALD web coating system 100 includes rollers 102 that support a web substrate 104 as it transports through a plurality of chambers where layers are deposited by ALD. In addition, the ALD web coating system 100 includes a series of chambers that purge the surface of the web substrate 104 with a purge gas and then pump the purge gas from the surface of the web substrate 104 prior to exposing the web substrate 104 to precursor gases. More specifically, in one embodiment of the present invention, the ALD web coating system includes a linear combination of nine process chambers that can be repeated along the web substrate 104 being processed any number of times and in any location.

The series of nine process chambers from left-to-right that process a web substrate moving from left-to-right around the rollers 102 include a first purge gas chamber 106 having an open surface exposed to the web substrate 104 on one end that forms a low gas conductance passage or baffle with the web substrate 104 and a connection to a gas manifold 105 on the other end. The first purge gas chamber 106 is coupled to a purge gas source through the gas manifold 105 and a valve. Numerous types of purge gases can be used. For example, the purge gas can be an inert gas, such as nitrogen and argon. The first purge gas chamber 106 is used to exchange residual gas on the surface of the web substrate 104 with the purge gas.

A first vacuum chamber 108 is positioned in series with the first purge gas chamber 106 so that the web substrate 104 passes directly from the first purge gas chamber 106 to the first vacuum chamber 108. The first vacuum chamber 108 has an open surface exposed to the web substrate 104 on one end that forms a baffle with the web substrate 104 and a connection to the gas manifold 105 on the other end. The first vacuum chamber 108 is coupled to a vacuum pump though the gas manifold 105 that evacuates the first vacuum chamber 106 including the surface of the web substrate 104 to a desired pressure. The first vacuum chamber 106 is used to remove residual purge gas on the web substrate 104. The web substrate 104 is now prepared for receiving reactant gases.

A first precursor reaction chamber 110 is positioned in series with the first pump out gas chamber 108 so that the web substrate 104 passes directly from the first vacuum chamber 108 to the first precursor reaction chamber 110 without being exposed to any contaminating materials. The first precursor reaction chamber 110 has an open surface on one end that is exposed to the web substrate 104 that forms a baffle with the web substrate 104 and a connection to the gas manifold 105 on the other end. The first precursor reaction chamber 110 is coupled to a first precursor gas source through the gas manifold 105 and a valve. The first precursor reaction chamber 110 exposes the web substrate 104 to a predetermined quantity of the first precursor gas molecules for predetermined time that depends on the translation rate of the web substrate.

A second vacuum chamber 112 is positioned in series with the first precursor reaction chamber 110 so that the web substrate 104 passes directly from the first precursor reaction chamber 110 to the second vacuum chamber 112. The second vacuum chamber 112 has an open surface on one end that is exposed to the web substrate 104 that forms a baffle with the web substrate 104. The second vacuum chamber 112 is coupled to a vacuum pump through the gas manifold 105 that evacuates the second vacuum chamber 112 to remove the first precursor gas and any gas by-products resulting from reactions on the surface of the web substrate. In various embodiments, the vacuum pump can be the same vacuum pump that is used to evacuate the first vacuum chamber 108 or can be a different vacuum pump.

A second purge gas chamber 114 is coupled to the second vacuum chamber 112. The second purge gas chamber 114 has an open surface exposed to the web substrate 104 on one end that forms a baffle with the web substrate 104 and a connection to the gas manifold 105 on the other end. The second purge gas chamber 114 is coupled to a purge gas source through the gas manifold 105 and a valve. Numerous types of purge gases can be used. For example, the purge gas can be an inert gas, such as nitrogen and argon. The second purge gas chamber 114 is used to exchange residual precursor gas and gas by-products on the surface of the web substrate 104 with the purge gas.

A third vacuum chamber 116 is positioned in series with the second purge gas chamber 114 so that the web substrate 104 passes directly from the second purge gas chamber 114 to the third vacuum chamber 116. The third vacuum chamber 116 has an open surface exposed to the web substrate 104 on one end that forms a baffle with the web substrate 104 and a connection to the gas manifold 105 on the other end. The third vacuum chamber 116 is coupled to a vacuum pump through the gas manifold 105 that evacuates the purge gas and any other residual gases from third vacuum chamber 116. In various embodiments, the vacuum pump can be the same vacuum pump that is used to evacuate the first and second vacuum chambers 108, 112 or can be a different vacuum pump.

A second precursor reaction chamber 118 is positioned in series with the second vacuum chamber 116 so that the web substrate 104 passes directly from the second vacuum chamber 116 to the second precursor reaction chamber 118 without being exposed to any contaminating materials. The second precursor reaction chamber 118 has an open surface exposed to the web substrate 104 on one end that forms a baffle with the web substrate 104 and a connection to the gas manifold 105 on the other end. The second precursor reaction chamber 118 is coupled to a second precursor gas source through the gas manifold 105 and a valve. The second precursor reaction chamber 118 exposes the web substrate 104 to a predetermined quantity of the second precursor gas molecules for predetermined time that depends on the translation rate of the web substrate.

The second vacuum chamber 112, the second purge gas chamber 114, and the third vacuum chamber 116, which are positioned between the first precursor reaction chamber 110 and the second precursor reaction chamber 118, prevent the first and second precursor gases from mixing and reacting in chambers positioned between the first and second reaction chambers 110, 118. For example, if there was only one common vacuum chamber between the first precursor reaction chamber 110 and the second precursor reaction chamber 118, the first and second precursor gases could mix and then react to form a material in the common vacuum chamber that will result in material build up in the common vacuum chamber and that can cause contamination on the web substrate 104.

A fourth vacuum chamber 120 is positioned in series with the second precursor reaction chamber 118 so that the web substrate 104 passes directly from the second precursor reaction chamber 118 to the fourth vacuum chamber 120. The fourth vacuum chamber 120 has an open surface exposed to the web substrate 104 on one end that forms a baffle with the web substrate 104 and a connection to the gas manifold 105 on the other end. The fourth vacuum chamber 120 is coupled to a vacuum pump through the gas manifold 105 that evacuates the fourth vacuum chamber 120 to remove the second precursor gas and any gas by-products resulting from reactions on the surface of the web substrate. In various embodiments, the vacuum pump can be the same vacuum pump that is used to evacuate the first, second, and third vacuum chambers 108, 112, and 116 or can be a different vacuum pump.

A third purge gas chamber 122 is coupled to the fourth vacuum chamber 120. The third purge gas chamber 122 has an open surface exposed to the web substrate 104 on one end that forms a baffle with the web substrate 104 and a connection to the gas manifold 105 on the other end. The third purge gas chamber 122 is coupled to a purge gas source through the gas manifold 105 and a valve. Numerous types of purge gases can be used. For example, the purge gas can be an inert gas, such as nitrogen and argon. The third purge gas chamber 122 is used to exchange residual precursor gas and gas by-products on the surface of the web substrate 104 with the purge gas.

The linear combination of the nine process chambers including the first purge gas chamber 106, the first vacuum chamber 108, the first precursor reaction chamber 110, the second vacuum chamber 112, the second purge gas chamber 114, the third vacuum chamber 116, the second precursor reaction chamber 118, the fourth vacuum chamber 120, and the third purge gas chamber 122 can be followed by any number of additional linear combinations of these nine process chambers. The additional linear combinations of these nine process chambers can be positioned direction adjacent to the first nine process chambers or can be positioned at some other location along the web substrate 104.

It should be understood that each of these nine process chambers can have its own specific chamber design. For example, the desired chamber size typically varies depending on the gas flow rate and pressure requirements. In most systems, the chamber size is chosen to be large enough to enable a uniform pressure across the web substrate 104 over the entire length of the web substrate. Uniform pressure is important because the surface reaction rate depends on the chamber pressure and exposure time. Exposure time is determined by the speed of the web substrate 104 and width of the precursor chamber along the direction of motion. A precursor gas injection manifold with multiple injection points can help minimize the precursor pressure differential across the web. Also, in some embodiments, it is desirable to combine a purge gas chamber and a vacuum chamber into a single chamber.

It should be understood by those skilled in the art that the schematic diagram shown in FIG. 1 is only a schematic representation and that various additional elements that are not shown, such as a system chamber, additional rollers to support the web substrate 104, valves, and vacuum pumps would be necessary to complete a functional apparatus. In addition, one skilled in the art will appreciate that there are numerous variation of the linear combinations of process chambers described in connection with FIG. 1. For example, in one embodiment, one of the second vacuum chamber 112 and the second purge gas chamber 114 is eliminated. In other more basic embodiments of the invention, only the first precursor reaction chamber 110, the vacuum chamber 112, and the second precursor reaction chamber 118 are included in the web coating system.

Each of the chambers shown in FIG. 1 is formed of solid walls with one surface exposed to the web substrate 104. The solid walls include a baffle that is positioned in close proximity to the web substrate 104. For example, in some embodiments, the baffle is positioned approximately 0.1 to 2.0 millimeters away from the surface of the web substrate. Numerous types of baffles can be used. For example, the baffle can be a corrugated baffle that isolates the chambers. However, in many embodiments, the baffle is far enough away from the surface of the web substrate 104 and/or is flexible enough to allow gas under pressure to exit the chamber as shown in FIG. 1 while still maintaining the desired chamber pressure.

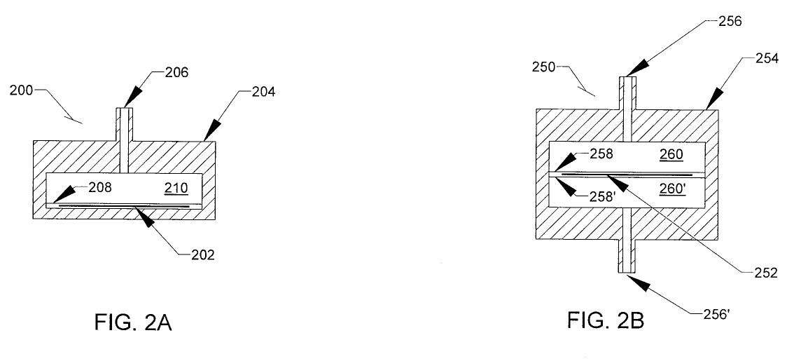

FIG. 2A is a cross-sectional view of a single surface web coating system 200 according to the present invention illustrating a web substrate 202 in a manifold 204 comprising a plurality of chambers. The manifold 204 includes a port 206 that can be coupled to a gas source or to a vacuum pump depending upon the type of chamber. The cross-sectional view shows the baffles 208 that isolate the chambers 210 to maintain a desired local pressure inside of the chambers 210 and at the surface of the web substrate 202. In some embodiments, the gap between the baffles 208 and the surface of the web substrate 202 is in the range of approximately 0.1 to 2.0 mm. However, smaller and larger gaps are possible. In various embodiments, the baffles 208 can be different and/or have different gaps depending upon the type of chamber used and the desired local pressures inside the chambers.

FIG. 2B is a cross-sectional view of a dual-surface web coating system 250 according to the present invention illustrating a web substrate 252 in a manifold 254 comprising a first plurality of chambers on one side of the web substrate 252 and a second plurality of chambers on the other side of the web substrate 252. The manifold 254 includes ports 256, 256′ that can be coupled to a gas source or to a vacuum pump depending upon the type of chamber. The cross-sectional view shows the baffles 258, 258′ that isolate the chambers 260, 260′ from the web substrate 252 to maintain a desired local pressure inside of the chambers 260, 260′ and at the surface of the web substrate 202. In some embodiments, the gap between the baffles 258 and the surface of the web substrate 252 is in the range of approximately 0.1 to 2.0 mm. However, smaller and larger gaps are possible. In various embodiments, the baffles 258, 258′ can be different and/or have different gaps depending upon the type of chamber used and the desired local pressures inside the chambers.

In another embodiment, the series of chambers comprising the ALD web coating system of the present invention are formed without solid wall. For example, a gas curtain can be used instead of solid walls to separate the chambers. In such a deposition apparatus, the precursor gases would mix on either side of the web substrate where they are pumped out. One skilled in the art will appreciate that the chambers comprising the ALD web coating system of the present invention can have ridged or flexible walls or a combination of both ridged and flexible walls.

The operation of the web coating system 100 can be understood by following a section of web substrate 104 as the rollers 102 transport it through the series of nine process chambers from right-to-left. The rollers 102 first transport the section of web substrate 104 to the first purge gas chamber 106 where the surface of the web substrate 104 is exposed to purge gas that displaces any residual gas on the surface of the web substrate 104. The rollers 102 then transport the section of the web substrate 104 to the first vacuum chamber 108 where residual purge gas and other gases and impurities on the web substrate 104 are evacuated.

The rollers 102 then transport the section of the web substrate 104 to the first precursor reaction chamber 110 where first precursor gas molecules are injected in the chamber 110 to create a desired partial pressure of the first precursor gas on the surface of the section of the web substrate 104. In some deposition processes, the first precursor gas and another precursor gas are injected into the chamber 110. In some deposition processes, the second precursor gas and a non-reactive gas are injected into the chamber 118. In some embodiments, the temperature of the section of the web substrate 104 and/or the chamber 110 is controlled to a temperature that promotes a desired reaction at the surface of the web substrate 104. In various embodiments, the web substrate 104 can be positioned in direct thermal contact with a heater or temperature controller and/or can be positioned proximate to a heat source.

The rollers 102 then transport the section of the web substrate 104 to the second vacuum chamber 112 where the first precursor gas and any gas by-products are evacuated. The rollers 102 then transport the section of the web substrate 104 to the second purge gas chamber 114 where any residual first precursor gas and any remaining gas by-products on the surface of the web substrate 104 are exchange with the purge gas. The rollers 102 then transport the section of the web substrate 104 to the third vacuum chamber 116 where residual precursor gas and gas by-products are evacuated from the surface of the web substrate 104.

The rollers 102 then transport the section of the web substrate 104 to the second precursor reaction chamber 118 where second precursor gas molecules are injected in the chamber 118 to create a desired partial pressure of the second precursor gas on the surface of the section of the web substrate 104. In some deposition processes, the second precursor gas and another precursor gas are injected into the chamber 118. In other deposition processes, the second precursor gas and a non-reactive gas are injected into the chamber 118. In some embodiments, the temperature of the section of the web substrate 104 and/or the chamber 118 is controlled to a temperature that promotes a desired reaction on the surface of the web substrate 104. The rollers 102 then transport the section of the web substrate 104 to the fourth vacuum chamber 120 where the second precursor gas and any gas by-products resulting from reactions are evacuated from the surface of the web substrate. The rollers 102 then transport the section of the web substrate 104 to the third purge gas chamber 122 where any residual second precursor gas and any remaining gas by-products on the surface of the web substrate 104 are exchange with the purge gas.

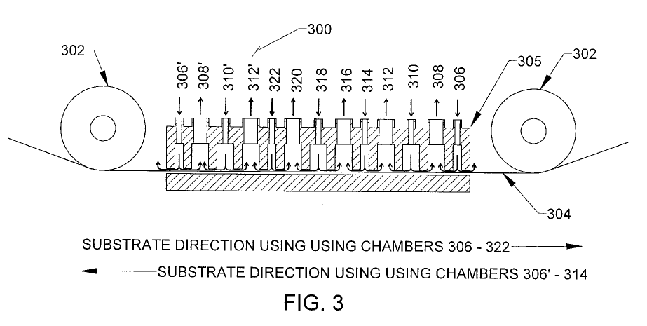

FIG. 3 illustrates a schematic view of a bi-directional ALD web coating system 300 having a linear combination of the thirteen process chambers according to the present invention. The bi-directional web coating system 300 includes rollers 302 that support a web substrate 304 as it transports in either direction through a series of thirteen chambers that purge the surface of the web substrate 304 with a purge gas and then pump the purge gas from the surface of the web substrate 304 prior to exposing the web substrate 304 to a precursor gas. The thirteen process chambers allow the web coating system 300 to deposit material by ALD when the web substrate 104 is traveling from right-to-left and also when the web substrate 104 is traveling from left-to-right. One feature of the bi-directional web coating system 300 is that it can be both compact in size and have high throughput.

The bi-directional web coating system 300 includes the nine process chambers described in connection with the web coating system 100. In addition, the bi-directional web coating system 300 includes four additional process chambers that prepare the web substrate 304 for exposure to the first precursor gas, exposure the web substrate 304 to the first precursor gas, and then purge the first precursor gas and any gas by-products from the surface of the web substrate 304.

Referring to FIG. 3 and to the description of the web coating system shown in FIG. 1, when the web substrate 304 is transported by the rollers 302 from left-to-right, the web substrate 304 is exposed to the nine process chambers described in connection with FIG. 1. That is, a section of the web substrate 304 first passes through a purge gas chamber 306, and then through a vacuum chamber 308, and then through a precursor reaction chamber 310 where the section of the web substrate 304 is exposed to the first precursor gas at a desired partial pressure to form an atomic layer.

The rollers 302 then transport the section of the web substrate 304 to the vacuum chamber 312, and then to the purge gas chamber 314, and then to the vacuum chamber 316, and then to the second precursor reaction chamber 318 where the section of the web substrate 304 is exposed to the second precursor gas at a desired partial pressure to form a second atomic layer. The rollers 302 then transport the section of the web substrate 304 to the vacuum chamber 320 where the second precursor gas and any gas by-products resulting from reactions are evacuated from the surface of the web substrate, and then to the purge gas chamber 322. The remaining chambers 312′, 310′, 308′, and 306′ are not used when the section of web substrate 304 is transported by the rollers 302 from left-to-right.

When the section of the web substrate 304 is transported by the rollers 302 in the opposite direction, from right-to-left, the web substrate 304 is also exposed to nine process chambers. The web substrate 304 first passes through a purge gas chamber 306′, and then through a vacuum chamber 308′, and then through a first precursor reaction chamber 310 ′, which is identical to the first precursor reaction chamber 310, where the section of the web substrate 304 is exposed to the first precursor gas at a desired partial pressure to form an atomic layer.

The rollers 302 then transport the section of the web substrate 304 to a vacuum chamber 312′, and then to the purge gas chamber 322, and then to the vacuum chamber 320, and then to the second precursor reaction chamber 318 where the section of the web substrate 304 is exposed to the second precursor gas at a desired partial pressure to form a second atomic layer. The rollers 302 then transport the section of the web substrate 304 to the vacuum chamber 316 where the second precursor gas and any gas by-products resulting from reactions are evacuated from the surface of the web substrate 304, and then to the purge gas chamber 314. The remaining chambers 312, 310, 308, and 306 are not used when the section of web substrate 304 is transported by the rollers 302 from right-to-left.

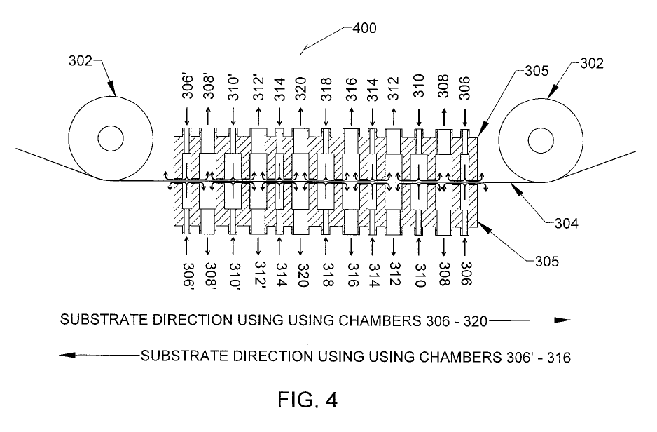

FIG. 4 illustrates a schematic view of a bi-directional dual-surface web coating system 400 according to the present invention. The bi-directional dual-surface web coating system 400 is identical to the bi-directional ALD web coating system described in connection with FIG. 3. However, the bi-directional dual-surface web coating system 400 includes process chambers on both sides the web substrate 304.

There are many deposition applications where it is desirable to deposit material on both sides of a web substrate 304. One such application is to fabricate and encapsulate organic light emitting diodes. In many embodiments of the present invention, the process chambers on each side of the web substrate 304 are identical as shown in FIG. 4. However, one skilled in the art will appreciate that a particular process may require that the process chambers on one side of the web substrate 304 be different from the process chambers on the other side of the web substrate 306. In addition, one skilled in the art will appreciate that the process chambers on one side of the web substrate 304 do not need to be aligned with the process chambers on the other side of the web substrate 306.

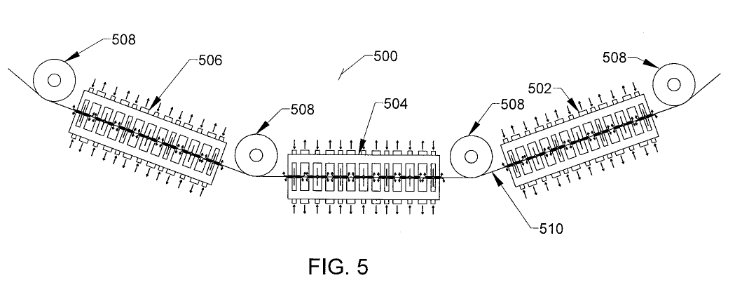

FIG. 5 illustrates a schematic view of a bi-directional dual-surface web coating system 500 including a plurality of linear combinations of process chambers according to the present invention. FIG. 5 shows three bi-directional dual-surface web coating system 502, 504, and 506 that can be identical to the bi-directional ALD web coating system described in connection with FIG. 3. In various embodiments, each of the three bi-directional dual-surface web coating system 502, 504, and 506 can have the same chambers or can have different chambers. Rollers 508 are used to transport the web substrate 510 through the bi-directional dual-surface web coating system 502, 504, and 506 as described in connection with FIG. 2.

One skilled in the art will appreciate that there are many possible configurations of the web coating system according to the present invention. For example, in one embodiment of the invention, the web substrate is positioned in a fixed location and the process chambers are transported relative to the web substrate. In another embodiment, both the web substrate and the process chambers are transported relative to each other.

### Equivalents

While the applicant's teachings are described in conjunction with various embodiments, it is not intended that the applicant's teachings be limited to such embodiments. On the contrary, the applicant's teachings encompass various alternatives, modifications, and equivalents, as will be appreciated by those of skill in the art, which may be made therein without departing from the spirit and scope of the teaching.

What is claimed is:

1. A web substrate atomic layer deposition system comprising:
a) at least one roller that transports a first surface of a web substrate through processing chambers in a first direction; and
b) a plurality of processing chambers positioned so that the at least one roller transports the first surface of the web substrate through the plurality of processing chamber in the first direction, the plurality of processing chambers comprising a first precursor reaction chamber that exposes the first surface of the web substrate to a desired partial pressure of first precursor gas, thereby forming a first layer on the first surface of the web substrate, a purging chamber that purges the first surface of the web substrate with a purge gas, a vacuum chamber that removes gas from the first surface of the substrate, and a second precursor reaction chamber that exposes the first surface of the web substrate to a desired partial pressure of the second precursor gas, thereby forming a second layer on the first surface of the web substrate.

2. The deposition system of claim 1 wherein the plurality of process chambers are attached.

3. The deposition system of claim 1 wherein the purging chamber and the vacuum chamber comprise a single chamber.

4. The deposition system of claim 1 wherein one end of each of the plurality of process chambers is attached to a gas manifold.

5. The deposition system of claim 4 wherein the gas manifold is coupled to a temperature controller that controls a temperature of the plurality of chambers.

6. The deposition system of claim 1 wherein the at least one roller transports the first surface of the web substrate through the plurality of processing chamber in both a first and a second direction.

7. The deposition system of claim 1 wherein at least one of the first and the second precursor reaction chamber is coupled to both a precursor gas source and a non-reactive gas source.

8. The deposition system of claim 1 wherein at least one of the first and the second precursor reaction chamber is coupled to at least two precursor gas sources.

9. The deposition system of claim 1 further comprising a heater positioned proximate to the web substrate that controls a temperature of the web substrate when it transports through at least one of the first and the second precursor reaction chambers.

10. The deposition system of claim 1 further comprising a heater positioned proximate to the plurality of processing chambers that controls a temperature of the plurality of processing chambers.

11. The deposition system of claim 1 further comprising a heater coupled to the plurality of processing chambers that controls a temperature of the plurality of processing chambers.

12. The deposition system of claim 1 further comprising a second plurality of processing chambers positioned opposite to the plurality of processing chambers and being positioned so that the at least one roller transports a second surface of the web substrate through the second plurality of processing chamber.

13. The deposition system of claim 12 wherein the second plurality of processing chambers comprises a first precursor reaction chamber that exposes the second surface of the web substrate to a desired partial pressure of first precursor gas, thereby forming a first layer on the second surface of the web substrate, a purging chamber that purges the second surface of the web substrate with a purge gas, a vacuum chamber that removes gas from the second surface of the substrate, and a second precursor reaction chamber that exposes the second surface of the web substrate to a desired partial pressure of the second precursor gas, thereby forming a second layer on the second surface of the web substrate.

14. The deposition system of claim 12 wherein the second plurality of processing chambers is positioned opposite to and is aligned with the plurality of processing chambers.

15. The deposition system of claim 1 further comprising a second plurality of processing chambers positioned adjacent to the plurality of processing chambers so that the at least one roller transports the first surface of the web substrate through the second plurality of processing chamber.

16. The deposition system of claim 15 wherein the second plurality of processing chambers comprises a first precursor reaction chamber that exposes the first surface of the web substrate to a desired partial pressure of first precursor gas, thereby forming a first layer on the first surface of the web substrate, a purging chamber that purges the first surface of the web substrate with a purge gas, a vacuum chamber that removes gas from the first surface of the web substrate, and a second precursor reaction chamber that exposes the first surface of the web substrate to a desired partial pressure of the second precursor gas, thereby forming a second layer on the first surface of the web substrate.

17. A web substrate atomic layer deposition system comprising:
a) at least one roller that transports a first surface of a web substrate through processing chambers in a first direction; and
b) a plurality of processing chambers positioned so that the at least one roller transports the first surface of the web substrate in the first direction through the plurality of processing chamber, the plurality of processing chambers comprising:
i) a purging chamber coupled to a purge gas source, the purging chamber purging the first surface of the web substrate with the purge gas as it transports through the purging chamber;
ii) a vacuum chamber being coupled a vacuum pump, the vacuum chamber evacuating the first surface of the web substrate as it transports through the vacuum chamber, thereby removing gas from the first surface of the substrate;
iii) a first precursor reaction chamber coupled to a first precursor gas source, the first precursor reaction chamber exposing the first surface of the web substrate to a desired partial pressure of the first precursor gas, thereby forming a first layer on the surface of the web substrate;
iv) a second purging chamber coupled to a purge gas source, the second purging chamber purging the first surface of the web substrate with the purge gas as it transports through the purging chamber;
v) a second vacuum chamber coupled a vacuum pump, the second vacuum chamber evacuating the first surface of the web substrate as it transports through the vacuum chamber, thereby removing gas from the first surface of the substrate; and
vi) a second precursor reaction chamber coupled to a second precursor gas source, the second precursor reaction chamber exposing the first surface of the web substrate to a desired partial pressure of the second precursor gas, thereby forming a second layer on the surface of the web substrate.

18. The deposition system of claim 17 wherein the purging chamber and the vacuum chamber comprise a single chamber.

19. The deposition system of claim 17 wherein the second purging chamber and the second vacuum chamber comprise a single chamber.

20. The deposition system of claim 17 wherein at least one of the first and the second precursor reaction chamber is coupled to a non-reactive gas source.

21. The deposition system of claim 17 further comprising a heater positioned proximate to the web substrate that controls a temperature of the web substrate when it transports through at least one of the first and the second precursor reaction chambers.

22. The deposition system of claim 17 further comprising a heater positioned proximate to the plurality of processing chambers that controls a temperature of the plurality of processing chambers.

23. The deposition system of claim 17 further comprising a heater coupled to the plurality of processing chambers that controls a temperature of the plurality of processing chambers.

24. The deposition system of claim 17 wherein the at least one roller transports the web substrate through the plurality of processing chamber in both the first direction and a second direction.

25. The deposition system of claim 17 further comprising a second plurality of processing chambers, which are identical to the plurality of processing chambers, that are positioned adjacent to the plurality of plurality of process chambers so that the at least one roller transports the first surface of the web substrate in the first direction through the second plurality of processing chambers comprising.

26. The deposition system of claim 17 further comprising a second plurality of processing chambers, which are identical to the plurality of process chambers, the second plurality of processing chambers being positioned so that the at least one roller transports a second surface of the web substrate through the second plurality of processing chambers.

27. A method of depositing material on a web substrate, the method comprising:
a) transporting a surface of a web substrate through a purging chamber that purges the surface of the web substrate with the purge gas;
b) transporting the surface of the web substrate through a vacuum chamber that evacuates the surface of the web;
c) transporting the surface of the web substrate through a first precursor reaction chamber that exposes the surface of the web substrate to a desired partial pressure of the first precursor gas, thereby forming a first layer on the surface of the web substrate;
d) transporting the surface of the web substrate through a second purging chamber that purges the first precursor gas and gas by-products from the surface of the web substrate with the purge gas;
e) transporting the surface of the web substrate through a second vacuum chamber that evacuates the surface of the web; and
f) transporting the surface of the web substrate through a second precursor reaction chamber that exposes the surface of the web substrate to a desired partial pressure of the second precursor gas, thereby forming a second layer on the surface of the web substrate.

28. The method of claim 27 further comprising repeating steps a) through f) a plurality of times.

29. The method of claim 27 wherein the transporting the surface of the web substrate in steps a) through f) is performed in one direction.

30. The method of claim 27 wherein the transporting the surface of the web substrate in steps a) through f) is performed in a first and a second direction.

31. The method of claim 27 wherein steps a) through f) are performed on a first and second surface of the web substrate.

32. The method of claim 27 wherein a least one of the first and the second precursor gases are mixed with a non-reactive gas.

33. The method of claim 27 further comprising heating the web substrate while transporting the surface of the web substrate through at least one of the first and the second precursor reaction chamber.

34. The method of claim 27 further comprising heating at least one of the first and the second precursor reaction chambers.
